(19) United States
(12) Patent Application Publication
(10) Pub. No.: US 2021/0319988 A1
(43) Pub. Date: Oct. 14, 2021

(54) SUBSTRATE SUPPORT STAGE, PLASMA PROCESSING SYSTEM, AND METHOD OF MOUNTING EDGE RING

(71) Applicant: TOKYO ELECTRON LIMITED, Tokyo (JP)

(72) Inventors: Kazuki MOYAMA, Miyagi (JP); Kazuya NAGASEKI, Miyagi (JP)

(73) Assignee: TOKYO ELECTRON LIMITED, Tokyo (JP)

(21) Appl. No.: 17/228,222

(22) Filed: Apr. 12, 2021

(30) Foreign Application Priority Data
Apr. 13, 2020 (JP) 2020-071899

(51) Int. Cl. H01J 37/32

(52) U.S. Cl. CPC H01J 37/32642; H01J 2237/208; H01J 37/32385; H01J 37/32733

(57) ABSTRACT

A substrate support stage includes a substrate mounting surface on which a substrate is mounted and a ring mount on which an edge ring is mounted. The edge ring is disposed so as to surround the substrate mounted on the substrate mounting surface. The ring mount is provided with a plurality of gas ejection ports configured to eject a gas toward a lower surface side of the edge ring to levitate the edge ring while the edge ring is being mounted on the ring mount, thereby allowing the gas to flow out from a gap between inner and outer peripheries of the lower surface side of the edge ring and the ring mount.

### CROSS-REFERENCE TO RELATED APPLICATIONS

This application is based on and claims priority from Japanese Patent Application No. 2020-071899, filed on Apr. 13, 2020 with the Japan Patent Office, the disclosure of which is incorporated herein in its entirety by reference.

### TECHNICAL FIELD

The present disclosure relates to a substrate support stage, a plasma processing system, and a method of mounting an edge ring.

### BACKGROUND

Japanese Patent Laid-Open Publication No. 2011-054933 discloses a substrate processing apparatus in which a substrate is disposed in a processing chamber and a focus ring is disposed to surround the substrate in order to perform a plasma processing on the substrate. This substrate processing apparatus includes a mounting stage provided with a susceptor having a substrate mounting surface on which the substrate is mounted and a focus ring mounting surface on which the focus ring is mounted. Further, the substrate processing apparatus disclosed in Japanese Patent Laid-Open Publication No. 2011-054933 includes a lifter pin and a transfer arm. The lifter pin is provided on the mounting stage to protrude from and retract to the focus ring mounting surface, and serves to lift the focus ring together with a positioning pin to separate the focus ring from the focus ring mounting surface. The transfer arm is provided outside the processing chamber to exchange the focus ring having the positioning pin attached thereto with the lifter pin through a carry-in/out opening provided in the processing chamber.

### SUMMARY

One aspect of the present disclosure is a substrate support stage including a substrate mounting surface on which a substrate is mounted and a ring mount on which an edge ring is mounted, the edge ring being disposed so as to surround the substrate mounted on the substrate mounting surface. The ring mount is provided with a plurality of gas ejection ports configured to eject a gas toward a lower surface side of the edge ring to levitate the edge ring while the edge ring is being mounted on the ring mount, thereby causing the gas to flow out from a gap between inner and outer peripheries of the lower surface side of the edge ring and the ring mount.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating an outline of a configuration of a plasma processing system according to the present embodiment.

FIG. 2 is a vertical cross-sectional view illustrating an outline of a configuration of a processing module.

FIG. 3 is an explanatory view schematically illustrating a state where an elevating member supports an edge ring having a tapered portion on the lower surface side above a ring mount in the present embodiment.

FIG. 4 is an explanatory view schematically illustrating a state where the elevating member is lowered, and the edge ring having the tapered portion on the lower surface side levitates on the ring mount.

FIG. 5 is an enlarged explanatory view of the edge ring and the ring mount in FIG. 4.

FIG. 6 is an explanatory view schematically illustrating a state where the edge ring having the tapered portion on the lower surface side is mounted on the ring mount.

FIG. 7 is an explanatory view schematically illustrating how a heat transfer gas is supplied to the edge ring after the edge ring having the tapered portion on the lower surface side is mounted on the ring mount.

FIG. 8 is an explanatory view schematically illustrating a state where a wafer is mounted on a substrate mount after the edge ring having the tapered portion on the lower surface side is mounted on the ring mount.

FIG. 9 is an explanatory view schematically illustrating a state where an edge ring having a concave portion on the lower surface side levitates on a ring mount.

FIG. 10 is an enlarged explanatory view of the edge ring and the ring mount in FIG. 9.

FIG. 11 is an explanatory view schematically illustrating how a heat transfer gas is supplied to the edge ring after the edge ring having the concave portion on the lower surface side is mounted on the ring mount.

FIG. 12 is an explanatory view schematically illustrating a state where an edge ring having a convex portion on the lower surface side levitates on a ring mount having a concave portion on the upper surface side.

FIG. 13 is an explanatory view schematically illustrating how a heat transfer gas is supplied to the edge ring after the edge ring having the convex portion on the lower surface side is mounted on the ring mount having the concave portion on the upper surface side.

FIG. 14 is an explanatory view schematically illustrating a state where an edge ring having a concave portion on the lower surface side levitates on a ring mount having a convex portion on the upper surface side.

FIG. 15 is an explanatory view schematically illustrating how a heat transfer gas is supplied to the edge ring after the edge ring having the concave portion on the lower surface side is mounted on the ring mount having the convex portion on the upper surface side.

FIG. 16 is an explanatory view schematically illustrating a state where an edge ring having a tapered concave portion on the lower surface side levitates on a ring mount.

FIG. 17 is an enlarged explanatory view of the edge ring and the ring mount in FIG. 16.

FIG. 18 is an explanatory view schematically illustrating how a heat transfer gas is supplied to the edge ring after the edge ring having the tapered concave portion on the lower surface side is mounted on the ring mount.

### DESCRIPTION OF EMBODIMENT

In the following detailed description, reference is made to the accompanying drawings, which form a part hereof. The illustrative embodiments described in the detailed description, drawing, and claims are not meant to be limiting. Other embodiments may be utilized, and other changes may be made without departing from the spirit or scope of the subject matter presented here.

In a process of manufacturing a semiconductor device, a plasma processing (e.g., etching) is performed on a substrate such as a semiconductor wafer (hereinafter referred to as a “wafer”) using a plasma. The plasma processing is performed on the wafer in a state where the wafer is mounted on a substrate support stage inside a decompressed processing container.

Further, in order to obtain good and uniform plasma processing results at a central portion and a peripheral edge portion of the substrate, an edge ring may be mounted on the substrate support stage so as to surround the substrate on the substrate support stage. The edge ring is mounted on an edge ring mount provided around the substrate on the substrate support stage.

The edge ring may be mounted on the edge ring mount by a transfer arm. That is, the transfer arm supporting the edge ring enters a processing chamber of a substrate processing apparatus from the outside of the processing chamber, so that the edge ring is mounted on a lift pin rising upward from an edge ring mounting surface. Then, the transfer arm exits from the processing chamber. Next, the lift pin is lowered, and the edge ring on the lift pin is mounted on the edge ring mount.

In order to mount the edge ring accurately at a predetermined mounting position, it is necessary to improve the mechanical accuracy of the transfer arm and strictly improve the accuracy of the mounting position by the transfer arm.

However, there is a limit to improving the accuracy of the mounting position simply by improving the mechanical accuracy of the transfer arm.

Therefore, the technique according to the present disclosure is to mount the edge ring on the edge ring mount with high accuracy.

Hereinafter, a substrate support stage, a plasma processing system, and a method of mounting an edge ring according to the present embodiment will be described with reference to the drawings. In the present specification and the drawings, elements having substantially the same functional configuration will be designated by the same reference numerals, so that duplicate descriptions thereof will be omitted.

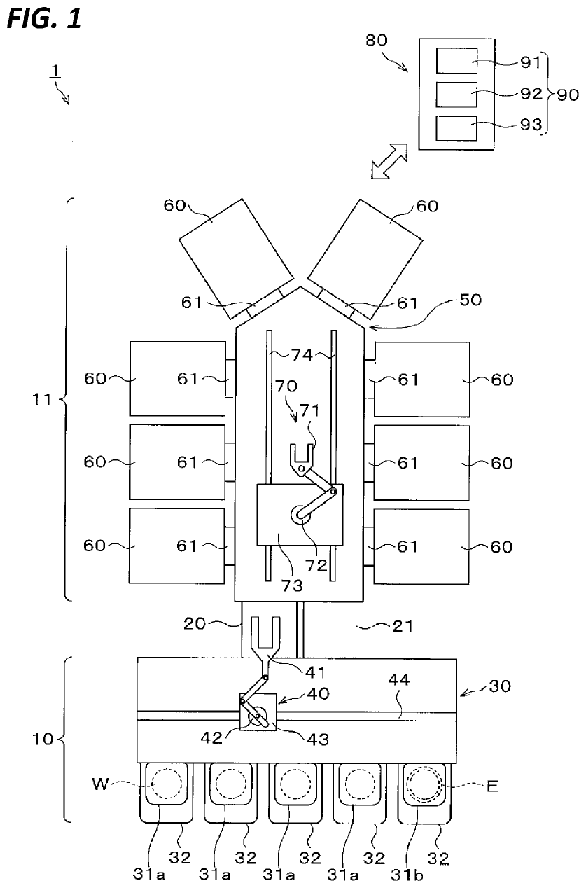

FIG. 1 is a plan view illustrating an outline of a configuration of a plasma processing system according to the present embodiment. In the plasma processing system 1 of FIG. 1, a wafer W as a substrate is subjected to a plasma processing such as, for example, etching using a plasma.

As illustrated in FIG. 1, the plasma processing system 1 has an atmospheric unit 10 and a decompression unit 11. The atmospheric unit 10 and the decompression unit 11 are integrally connected to each other via load lock modules 20 and 21. The atmospheric unit 10 includes an atmospheric module that performs a desired processing on the wafer W under an atmospheric pressure atmosphere. The decompression unit 11 includes a decompression module that performs a desired processing on the wafer W under a decompression atmosphere.

The load lock modules 20 and 21 are provided to interconnect a loader module 30 (to be described later) in the atmospheric unit 10 and a transfer module 50 (to be described later) in the decompression unit 11 via a gate valve (not illustrated). The load lock modules 20 and 21 are configured to temporarily hold the wafer W. Further, the load lock modules 20 and 21 are configured so that the inside thereof may be switched between the atmospheric pressure atmosphere and the decompression atmosphere.

The atmospheric unit 10 has the loader module 30 provided with a transfer device 40 (to be described later) and load ports 32 on which hoops 31a and 31b are mounted. The hoop 31a is capable of storing a plurality of wafers W, and the hoop 31b is capable of storing a plurality of edge rings E. The loader module 30 may be adjacently provided with an oriental module (not illustrated) which adjusts the horizontal orientation of the wafer W or the edge ring E, or a storage module (not illustrated) which stores the wafers W.

The inside of the loader module 30 is defined by a rectangular housing, and the inside of the housing is maintained in an atmospheric pressure atmosphere. A plurality of (e.g., five) load ports 32 are arranged side by side on one side surface forming the long side of the housing of the loader module 30. The load lock modules 20 and 21 are arranged side by side on the other side surface forming the long side of the housing of the loader module 30.

The transfer device 40 is provided inside the loader module 30 to transfer the wafer W or the edge ring E. The transfer device 40 has a transfer arm 41 that supports and moves the wafer W or the edge ring E, a turntable 42 that rotatably supports the transfer arm 41, and a base 43 on which the turntable 42 is mounted. Further, a guide rail 44 is provided inside the loader module 30 to extend in the longitudinal direction of the loader module 30. The base 43 is provided on the guide rail 44, and the transfer device 40 is configured to be movable along the guide rail 44.

The decompression unit 11 has a transfer module 50 that transfers the wafer W or the edge ring E and a processing module 60 as a plasma processing apparatus that performs a desired plasma processing on the wafer W transferred from the transfer module 50. The inside of each of the transfer module 50 and the processing module 60 is maintained in a decompression atmosphere. A plurality of (e.g., eight) processing modules 60 are provided for one transfer module 50. The number of processing modules 60 or the arrangement thereof is not limited to the present embodiment and may be arbitrarily set so long as at least one processing module that requires the replacement of the edge ring E is provided.

The inside of the transfer module 50 is configured by a polygonal (pentagonal in the illustrated example) housing, and connected to the load lock modules 20 and 21 as described above. The transfer module 50 transfers a wafer W carried into the load lock module 20 to one processing module 60, and carries the wafer W, which has been subjected to a desired plasma processing in the processing module 60, out to the atmospheric unit 21 via the load lock module 21. Further, the transfer module 50 transfers the edge ring E carried into the load lock module 20 to one processing module 60, and carries the edge ring E, which is a replacement target in the processing module 60, out to the atmospheric unit 10 via the load lock module 21.

The processing module 60 performs a plasma processing such as, for example, etching on the wafer W using plasma. Further, the processing module 60 is connected to the transfer module 50 via a gate valve 61. The configuration of the processing module 60 will be described later.

A transfer device 70 is provided inside the transfer module 50 to transfer the wafer W or the edge ring E. The transfer device 70 has a transfer arm 71 as a support which supports and moves the wafer W or the edge ring E, a turntable 72 which rotatably supports the transfer arm 71, and a base 73 on which the turntable 72 is mounted. Further, a guide rail 74 is provided inside the transfer module 50 to extend in the longitudinal direction of the transfer module 50. The base 73 is provided on the guide rail 74, and the transfer device 70 is configured to be movable along the guide rail 74.

The transfer module 50 receives the wafer W or the edge ring E held in the load lock module 20 by the transfer arm 71, and carries it into the processing module 60. Further, the transfer module 50 receives the wafer W or the edge ring E held in the processing module 60 by the transfer arm 71, and carries it out to the load lock module 21.

Further, the plasma processing system 1 has a control device 80. In one embodiment, the control device 80 processes computer executable instructions which cause the plasma processing system 1 to execute various processes described in the present disclosure. The control device 80 may be configured to control each of the other elements of the plasma processing system 1 to execute various processes described herein. In one embodiment, a part or all of the control device 80 may be included in the other elements of the plasma processing system 1. The control device 80 may include, for example, a computer 90. The computer 90 may include, for example, a central processing unit (CPU) 91, a storage 92, and a communication interface 93. The central processing unit 91 may be configured to perform various control operations based on programs stored in the storage 92. The storage 92 may include a random access memory (RAM), a read only memory (ROM), a hard disk drive (HDD), a solid state drive (SSD), or a combination thereof. The communication interface 93 may communicate with other elements of the plasma processing system 1 via a communication line such as a local area network (LAN).

Next, a wafer processing performed by using the plasma processing system 1 configured as described above will be described.

First, the wafer W is taken out from the desired hoop 31a and carried into the load lock module 20 by the transfer device 40. Then, the inside of the load lock module 20 is sealed and decompressed. Then, the inside of the load lock module 20 and the inside of the transfer module 50 are communicated with each other.

Next, the wafer W is held and transferred from the load lock module 20 to the transfer module 50 by the transfer device 70.

Next, the gate valve 61 is opened, and the wafer W is carried into the desired processing module 60 by the transfer device 70. Then, the gate valve 61 is closed, and a desired processing is performed on the wafer W in the processing module 60. The processing performed on the wafer W in the processing module 60 will be described later.

Next, the gate valve 61 is opened, and the wafer W is carried out from the processing module 60 by the transfer device 70. Then, the gate valve 61 is closed.

Next, the wafer W is carried into the load lock module 21 by the transfer device 70. Once the wafer W has been carried into the load lock module 21, the inside of the load lock module 21 is sealed and opened to the atmosphere. Then, the inside of the load lock module 21 and the inside of the loader module 30 are communicated with each other.

Next, the wafer W is held and returned from the load lock module 21 to the desired hoop 31a via the loader module 30 by the transfer device 40, and accommodated therein. In this way, a series of wafer processings in the plasma processing system 1 are completed.

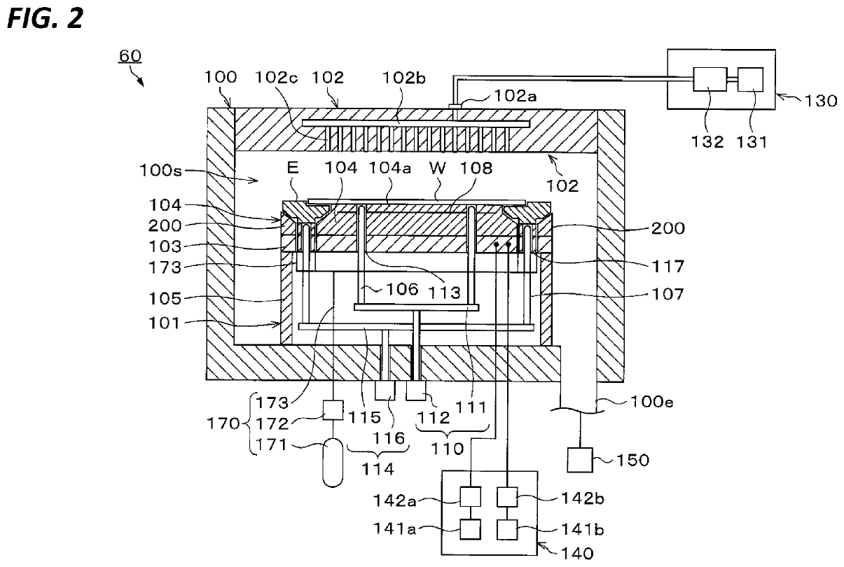

Subsequently, the processing module 60 will be described with reference to FIG. 2. FIG. 2 is a vertical cross-sectional view illustrating an outline of a configuration of the processing module 60. As illustrated in FIG. 2, the processing module 60 includes a plasma processing chamber 100 as a processing container, a gas supply 130, a radio-frequency (RF) power supply 140, an exhaust system 150, and a gas supply 170 which supplies a gas for levitating the edge ring E. Further, the processing module 60 also includes a voltage applicator 120 (to be described later). Furthermore, the processing module 60 includes a wafer support stage 101 as a substrate support stage and an upper electrode shower head 102.

The wafer support stage 101 is disposed in the lower region of a plasma processing space 100s in the plasma processing chamber 100 configured to be decompressible. The upper electrode shower head 102 may be disposed above the wafer support stage 101, and may function as a part of the ceiling of the plasma processing chamber 100.

The wafer support stage 101 is configured to support the wafer W in the plasma processing space 100s. In one embodiment, the wafer support stage 101 includes a lower electrode 103, an electrostatic chuck 104, an insulator 105, a lift pin 106, and a lift pin 107. Although not illustrated, the wafer support stage 101 includes a temperature adjustment module that adjusts at least one of the electrostatic chuck 104 and the wafer W to a target temperature. The temperature adjustment module may include a heater, a flow path, or a combination thereof. A temperature adjustment fluid such as a coolant or a heat transfer gas flows through the flow path.

The lower electrode 103 is formed of a conductive material such as, for example, aluminum. In one embodiment, the temperature adjustment module described above may be provided in the lower electrode 103.

The electrostatic chuck 104 is provided on the lower electrode 103, and attracts and holds the wafer W by an electrostatic force. In the electrostatic chuck 104, the upper surface of a central portion is formed higher than the upper surface of a peripheral edge portion. The upper surface 104a of the central portion of the electrostatic chuck 104 is a wafer mounting surface 104a on which the wafer W is mounted. The upper surface of the peripheral edge portion of the electrostatic chuck 104 is a ring mount 200 on which the edge ring E is mounted. Details of the edge ring E and the ring mount 200 will be described later.

An electrode 108 is provided in the central portion of the electrostatic chuck 104 to attract and hold the wafer W. The electrostatic chuck 104 has a configuration in which the electrode 108 is sandwiched between insulators formed of insulating materials. A voltage is applied to the electrode 108 from the voltage applicator (not illustrated) so that an electrostatic force is generated to attract the wafer W.

Further, for example, the central portion of the electrostatic chuck 104 is formed to have a diameter smaller than the diameter of the wafer W, so that the peripheral edge portion of the wafer W protrudes from the central portion of the electrostatic chuck 104 when the wafer W is mounted on the wafer mounting surface 104a.

Although not illustrated, a gas supply hole is formed in the wafer mounting surface 104a of the electrostatic chuck 104 in order to supply a heat transfer gas to the back surface of the wafer W mounted on the wafer mounting surface 104a. A heat transfer gas from a gas supply (not illustrated) is supplied from the gas supply hole. The gas supply may include one or more gas sources and one or more pressure controllers. In one embodiment, for example, the gas supply is configured to supply a heat transfer gas from the gas source to a heat transfer gas supply hole via the pressure controller.

The gas supply 170 supplies a levitation gas, for example, helium gas from a gas source 171 to the ring mount 200 by a gas supply path 173 via a gas mass flow controller or a pressure control type flow rate controller 172. The gas source 171 and the flow rate controller 172 are controlled by the control device 80 (illustrated in FIG. 1).

The insulator 105 is a cylindrical member formed of ceramics, and supports the lower electrode 103. For example, the insulator 105 is formed to have an outer diameter equivalent to the outer diameter of the lower electrode 103, and supports the peripheral edge portion of the lower electrode 103.

The lift pin 106 is a columnar member which is raised and lowered to protrude from and retract to the wafer mounting surface 104a of the electrostatic chuck 104, and is formed of, for example, ceramics. Three or more lift pins 106 are provided at intervals from each other along the circumferential direction of the electrostatic chuck 104, specifically, the circumferential direction of the wafer mounting surface 104a. For example, the lift pins 106 are equidistantly provided along the circumferential direction. The lift pins 106 are provided to extend in the vertical direction.

The lift pins 106 are connected to an elevating mechanism 110 which raises and lowers the lift pins 106. The elevating mechanism 110 has, for example, a support member 111 that supports the lift pins 106 and a drive unit 112 that generates a drive force to raise and lower the support member 111 to raise and lower the lift pins 106. The drive unit 112 has a motor (not illustrated) that generates the drive force.

The lift pin 106 is inserted through a through-hole 113 which extends downward from the wafer mounting surface 104a of the electrostatic chuck 104 to reach the bottom surface of the lower electrode 103. In other words, the through-hole 113 is formed to penetrate the central portion of the electrostatic chuck 104 and the lower electrode 103.

The lift pin 107 is a columnar member which is raised and lowered to protrude from and retract to the ring mount 200 at the periphery of the electrostatic chuck 104, and is formed of, for example, alumina, quartz, or SUS. Three or more lift pins 107 are provided at intervals from each other along the circumferential direction of the electrostatic chuck 104, specifically, the circumferential direction of the wafer mounting surface 104a and the ring mount 200. For example, the lift pins 107 are equidistantly provided along the circumferential direction. The lift pins 107 are provided to extend in the vertical direction, and are provided so that the upper end surface thereof is horizontal.

The thickness of the lift pin 107 is, for example, 1 mm to 3 mm.

The lift pins 107 are connected to an elevating mechanism 114 which drives the lift pins 107. The elevating mechanism 114 has, for example, a support member 115 that supports the lift pins 107 and a drive unit 116 that generates a drive force to raise and lower the support member 115 to raise and lower the lift pins 107. The drive unit 116 has a motor (not illustrated) that generates the drive force.

The lift pin 107 is inserted through a through-hole 117 which extends downward from the ring mount 200 of the electrostatic chuck 104 to reach the bottom surface of the lower electrode 103. In other words, the through-hole 117 is formed to penetrate the peripheral edge portion of the electrostatic chuck 104 and the lower electrode 103.

The upper electrode shower head 102 is configured to supply one or more processing gases from the gas supply 130 to the plasma processing space 100s. In one embodiment, the upper electrode shower head 102 has a gas inlet 102a, a gas diffusion chamber 102b, and a plurality of gas outlets 102c. The gas inlet 102a communicates with, for example, the gas supply 130 and the gas diffusion chamber 102b. The gas outlets 102c communicate fluidly with the gas diffusion chamber 102b and the plasma processing space 100s. In one embodiment, the upper electrode shower head 102 is configured to supply one or more processing gases from the gas inlet 102a to the plasma processing space 100s via the gas diffusion chamber 102b and the gas outlets 102c.

The gas supply 130 may include one or more gas sources 131 and one or more flow rate controllers 132. In one embodiment, for example, the gas supply 130 is configured to supply one or more processing gases from the respective corresponding gas sources 131 to the gas inlet 102a via the respective corresponding flow rate controllers 132. Each flow rate controller 132 may include, for example, a mass flow controller or a pressure control type flow rate controller. Further, the gas supply 130 may include one or more flow rate modulation devices that modulate or pulse the flow rate of one or more processing gases.

The RF power supply 140 is configured to supply RF power, for example, one or more RF signals to one or more electrodes such as the lower electrode 103, the upper electrode shower head 102, or both the lower electrode 103 and the upper electrode shower head 102. Thus, a plasma is generated from the one or more processing gases supplied to the plasma processing space 100s. Accordingly, the RF power supply 140 may function as at least a part of a plasma generator that generates a plasma from one or more processing gases in the plasma processing chamber. The RF power supply 140 includes, for example, two RF generators 141a and 141b and two matching circuits 142a and 142b. In one embodiment, the RF power supply 140 is configured to supply a first RF signal from the first RF generator 141a to the lower electrode 103 via the first matching circuit 142a. For example, the first RF signal may have a frequency in the range of 27 MHz to 100 MHz.

Further, in one embodiment, the RF power supply 140 is configured to supply a second RF signal from the second RF generator 141b to the lower electrode 103 via the second matching circuit 142b. For example, the second RF signal may have a frequency in the range of 400 kHz to 13.56 MHz. Alternatively, a direct current (DC) pulse generator may be used instead of the second RF generator 141b.

Furthermore, although not illustrated, other embodiments may be considered in the present disclosure. For example, in an alternative embodiment, the RF power supply 140 may be configured to supply a first RF signal from one RF generator to the lower electrode 103, to supply a second RF signal from another RF generator to the lower electrode 103, and to supply a third RF signal from the other RF generator to the lower electrode 103. In addition, in another alternative embodiment, a DC voltage may be applied to the upper electrode shower head 102.

Furthermore, in various embodiments, the amplitude of one or more RF signals (i.e., the first RF signal and the second RF signal) may be pulsed or modulated. The amplitude modulation may include pulsing the RF signal amplitude between the ON state and the OFF state or between two or more different ON states.

The exhaust system 150 may be connected to, for example, an exhaust hole 100e provided in the bottom of the plasma processing chamber 100. The exhaust system 150 may include a pressure valve and a vacuum pump. The vacuum pump may include a turbo molecular pump, a roughing vacuum pump, or a combination thereof.

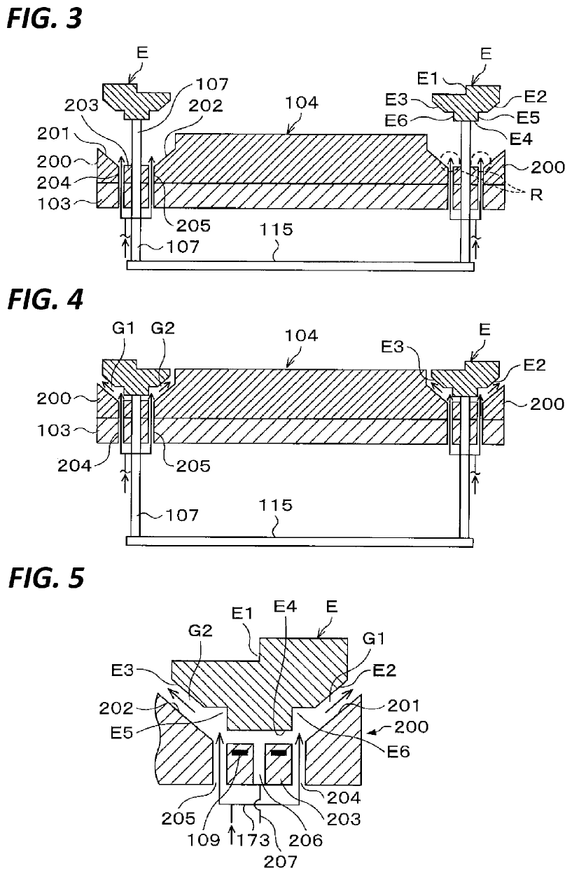

As illustrated in FIGS. 3 and 4, the edge ring E, which is mounted on the ring mount 200, is formed with a stepped portion E1 on the top thereof, so that the upper surface of an outer peripheral portion is formed higher than the upper surface of an inner peripheral portion. The inner peripheral portion of the edge ring E is formed to be introduced beneath the peripheral edge portion of the wafer W protruding from the central portion of the electrostatic chuck 104. That is, the inner diameter of the edge ring E is smaller than the outer diameter of the wafer W.

An annular outer tapered portion E2 and an annular inner tapered portion E3 are provided on the lower surface side of the edge ring E. An annular bottom portion E4 is provided between the outer tapered portion E2 and the annular inner tapered portion E3 to protrude downward. Then, a stepped portion E5 is formed between the outer tapered portion E2 and the annular bottom portion E4. A stepped portion E6 is formed between the inner tapered portion E3 and the annular bottom portion E4.

Meanwhile, the ring mount 200 has an annular outer slope portion 201 and an annular inner slope portion 202 which are wider upward in a tapered shape and an annular mounting portion 203 formed at the bottom between the outer slope portion 201 and the inner slope portion 202. Then, as illustrated in FIG. 5, an outer ejection port 204 and an inner ejection port 205 are provided in the outer periphery and the inner periphery of the annular mounting portion 203 to communicate with the gas supply path 173 to which the gas is supplied from the gas source 171 described above. Each of the outer ejection port 204 and the inner ejection port 205 is formed in a plural number at equal intervals along the circumferential direction. Annular grooves communicating with the outer ejection port 204 and the inner ejection port 205 may be formed in the outer periphery and the inner periphery (e.g., the portion indicated by R in FIG. 3) of the annular mounting portion 203.

The outer slope portion 201 and the inner slope portion 202 of the ring mount 200 have a shape capable of accommodating the outer tapered portion E2 and the inner tapered portion E3 of the edge ring E. The shape capable of accommodating the outer tapered portion E2 and the inner tapered portion E3 means, for example, a shape that corresponds to the inclination or length of the faces of the outer tapered portion E2 and the inner tapered portion E3. Further, the annular mounting portion 203 of the ring mount 200 may come into close contact with the annular bottom portion E4 of the edge ring E.

Further, the annular mounting portion 203 of the ring mount 200 is provided with a heat transfer gas ejection port 206. The ejection port 206 leads to the heat transfer gas supply path 207. In the example illustrated in FIG. 5, the ejection port 206 is provided separately from the through-hole 117 in which the lift pin 107 moves up and down, but the ejection port 206 may be provided in the upper surface of the through-hole 117. An electrode 109 is provided in the annular mounting portion 203 to generate an electrostatic force. As illustrated in FIG. 7 to be described later, the electrode 109 is electrically connected to the voltage applicator 120. The electrode 109 is, for example, a bipolar type, but may be a unipolar type.

The material of the edge ring E, which may be used herein, is an insulating material, for example, quartz. In addition, silicon (Si) or silicon carbide (SiC) may be used as the material of the edge ring E.

Next, an example of a wafer processing performed by using the processing module 60 will be described. The processing module 60 performs a processing such as etching processing, film forming processing, or diffusion processing on the wafer W.

First, the wafer W is carried into the plasma processing chamber 100, and the wafer W is mounted on the electrostatic chuck 104 by the rising and lowering of the lift pin 106. Then, a DC voltage is applied to the electrode 108 of the electrostatic chuck 104 from a DC power supply 121c, so that the wafer W is electrostatically attracted to and held by the electrostatic chuck 104 by an electrostatic force. Further, after the carry-in of the wafer W, the inside of the plasma processing chamber 100 is decompressed to a predetermined degree of vacuum by the exhaust system 150.

Next, a processing gas is supplied from the gas supply 130 to the plasma processing space 100s via the upper electrode shower head 102. Further, radio-frequency power HF for plasma generation is supplied from the RF power supply 140 to the lower electrode 103, so that the processing gas is excited to generate a plasma. At this time, high frequency power LF for ion implantation may be supplied from the RF power supply 140. Then, the wafer F is subjected to a plasma processing by the action of the generated plasma.

When completing the plasma processing, the supply of the radio-frequency power HF from the RF power supply 140 and the supply of the processing gas from the gas supply 130 are stopped. In a case where the radio-frequency power LF is supplied during the plasma processing, the supply of the radio-frequency power LF is also stopped. Next, the supply of the DC voltage from the DC power supply 121c is stopped, and the attraction and holding of the wafer W by the electrostatic chuck 104 is stopped.

Then, the lift pin 106 raises the wafer W to separate the wafer W from the electrostatic chuck 104. At the time of this separation, a static elimination processing of the wafer W may be performed. Then, the wafer W is carried out from the plasma processing chamber 100, and a series of wafer processings are completed.

Subsequently, an example of a processing of installing the edge ring E in the processing module 60 which is performed by using the plasma processing system 1 described above will be described. The following processing is performed under the control of the control device 80.

First, the transfer arm 71 holding a replacement edge ring E is inserted into the decompressed plasma processing chamber 100 through a carry-in/out opening (not illustrated), and the replacement edge ring E is transferred above the ring mount 200 disposed around the electrostatic chuck 104.

Next, as illustrated in FIG. 3, the lift pin 107 is raised, and the edge ring E is delivered from the transfer arm 71 to the lift pin 107. Then, extraction of the transfer arm 71 from the plasma processing chamber 100, i.e., retraction of the transfer arm 71 and lowering of the lift pin 107 are performed. Then, a gas is ejected from the outer gas ejection port 204 and the inner gas ejection port 205 toward the lower surface side of the edge ring E.

Then, as the lift pin 107 is lowered, as illustrated in FIG. 4, on the lower surface side of the edge ring E, a gas flow path G1 is defined between the outer tapered portion E2 and the outer slope portion 201 and a gas flow path G2 is defined between the inner tapered portion E3 and the inner slope portion 202. Then, as illustrated in FIG. 5, when the edge ring E approaches the ring mount 200, the gas from the outer gas ejection port 204 and the inner gas ejection port 205 hits the stepped portions E5 and E6 on the lower surface side of the edge ring E, and flows out from the gas flow paths G1 and G2 along the outer tapered portion E2 and the inner tapered portion E3.

Here, at the time point when the buoyancy calculated from the area of the annular bottom portion E4, the cross-sectional areas of the gas flow paths G1 and G2, the viscosity of the gas, and the flow rate of the gas is balanced with the mass of the edge ring E, the edge ring E levitates and stands on the ring mount 200. Accordingly, the edge ring E does not fall even in a state where the lift pin 107 is subsequently lowered and is separated from the edge ring E to no longer support the edge ring E.

In this state, the gas from the outer gas ejection port 204 passes around the outer tapered portion E2 of the edge ring E through the gas flow path G1, and the gas from the inner gas ejection port 205 passes around the inner tapered portion E3 of the edge ring E through the gas flow path G2. That is, the gas from the outer gas ejection port 204 and the gas from the inner gas ejection port 205 flows to the gas flow paths G1 and G2, respectively, and flows out to the outer peripheral side and the inner peripheral side of the edge ring E, respectively. Thus, the position of the edge ring E is adjusted between the outer slope portion 201 and the inner slope portion 202 of the ring mount 200. That is, the distance between the outer tapered portion E2 of the edge ring E and the outer slope portion 201 of the ring mounting section 200 and the distance between the inner tapered portion E3 and the inner slope portion 202 of the ring mount 200 are respectively adjusted to be equal to each other over the entire circumference.

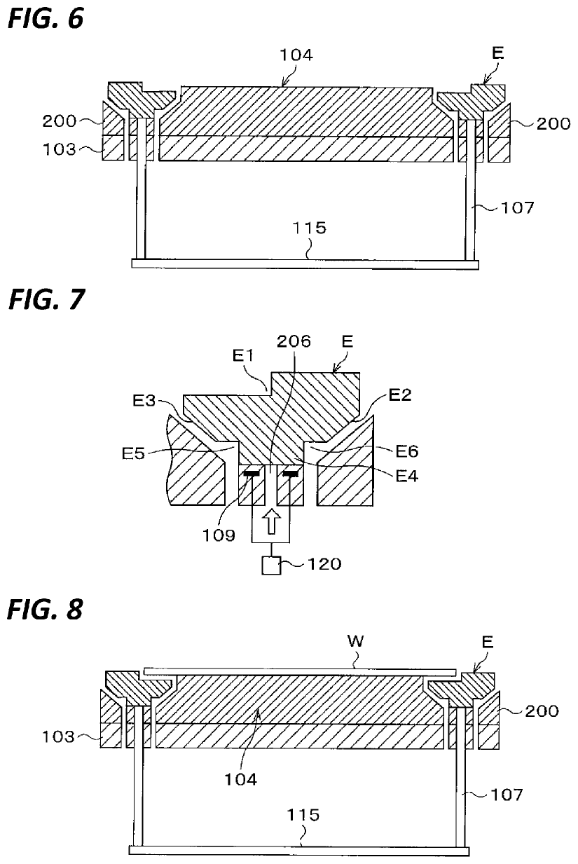

Then, by reducing the flow rate of the gas from the outer gas ejection port 204 and the inner gas ejection port 205, the edge ring E is gradually lowered as it is, and finally, as illustrated in FIGS. 6 and 7, the annular bottom portion E4 of the edge ring E comes into close contact with and is seated on the annular mounting portion 203 of the ring mount 200. Thus, the edge ring E is supported by the annular mounting portion 203 of the ring mount 200. That is, the edge ring E is mounted on the ring mount 200.

Then, by applying a voltage from the voltage applicator 120 to the electrode 109 in the annular mounting portion 203, the edge ring E is attracted to and held by the annular mounting portion 203 of the ring mount 200 by an electrostatic force generated at that time. In this way, after the edge ring E is attracted to and held by the annular mounting portion 203 of the ring mount 200, a heat transfer gas is ejected from the ejection port 206, so that the temperature of the edge ring E may be maintained in an appropriate range by the heat transfer gas. The voltage applicator 120 may also apply a voltage to the electrode 108 of the electrostatic chuck 104. Of course, the voltage applicator 120 may be configured to apply a voltage independently to the electrodes 108 and 109.

As described above, in the method of mounting the edge ring E according to the present embodiment, as the gas flows out to each of the outer peripheral side and the inner peripheral side of the edge ring E, the distance between the outer tapered portion E2 of the edge ring E and the outer slope portion 201 of the ring mount 200 and the distance between the inner tapered portion E3 of the edge ring E and the inner slope portion 202 of the ring mount 200 are adjusted to be equal to each other over the entire circumference. Therefore, the edge ring E may be mounted at a predetermined position of the ring mount 200 with high accuracy. Accordingly, it is not necessary to strictly control the stop position of the transfer arm 71 and improve the mechanical accuracy of the transfer arm 71 as compared with the related art.

Further, since the edge ring E and the ring mount 200 do not come into contact with each other until the edge ring E is mounted on the ring mount 200, the generation of particles may be suppressed.

Furthermore, in one form described above, the outer periphery of the lower surface of the edge ring E is formed by the outer tapered portion E2 and the inner periphery of the lower surface of the edge ring E is formed by the inner tapered portion E3, while the outer slope portion 201 and the inner slope portion 202 of the ring mount 200 accommodate the outer tapered portion E2 and the inner tapered portion E3. Accordingly, the levitation and position adjustment of the edge ring E by the levitation gas may be smoothly performed.

Further, in a case where it may be impossible to mount the edge ring E at a predetermined position of the ring mount 200 due to an external factor such as heat, the levitation gas is again ejected from the outer gas ejection port 204 and the inner gas ejection port 205 to the lower surface side of the edge ring E to levitate the edge ring E and perform the position adjustment thereof. Then, the mounting of the edge ring may be easily retried by reducing the flow rate of the gas to cause the edge ring to be seated. Whether or not the edge ring E is mounted at a predetermined position on the ring mount 200 may be determined by, for example, an optical sensor or a surveillance camera. Thus, when the edge ring E is not mounted at a predetermined position, the mounting of the edge ring may be automatically retried.

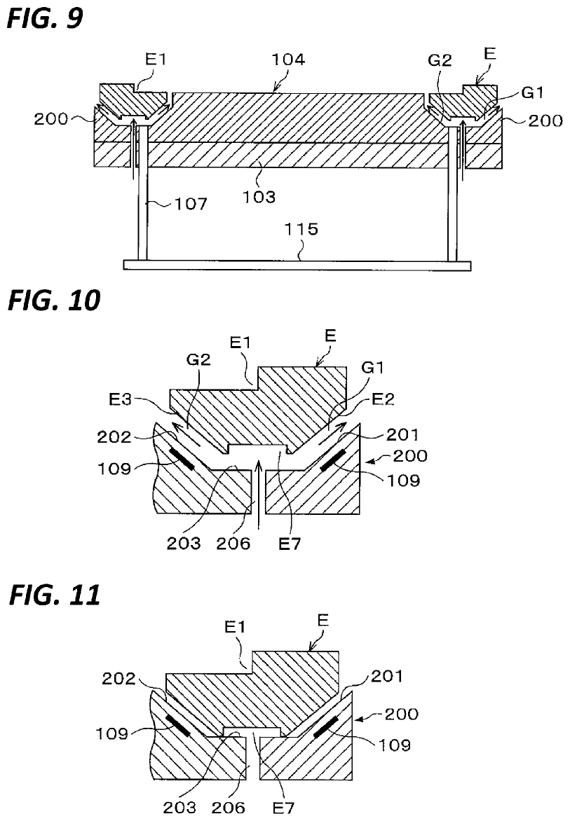

The shape and configuration of the edge ring E and the ring mount 200 are not limited to the above example. For example, in the edge ring E illustrated in FIGS. 9 and 10, an annular concave portion E7 is formed between the outer tapered portion E2 and the inner tapered portion E3. Accordingly, as illustrated in FIG. 10, the levitation gas ejected from the gas ejection port 206 first hits the annular concave portion E7, and then passes around the outer tapered portion E2 and the inner tapered portion E3 of the edge ring E through the gas flow paths G1 and G2. The position of the edge ring E having such a shape is also adjusted between the outer slope portion 201 and the outer tapered portion E2 and between the inner slope portion 202 and the inner tapered portion E3.

Then, when the flow rate of the levitation gas ejected from the ejection port 206 is gradually reduced to cause the edge ring E to be seated on the ring mount 200, as illustrated in FIG. 11, the peripheral edge portion of the annular concave portion E7 of the edge ring E comes into close contact with the annular mounting portion 203 of the ring mount 200. Thus, the annular concave portion E7 becomes a space closed in relation to the outside. Accordingly, a voltage is then applied to the electrode 109 to firmly hold the edge ring E on the ring mount 200 by an electrostatic force, and then, a heat transfer gas is ejected from, for example, the levitation gas ejection port 206, so that the temperature of the edge ring E may be maintained in an appropriate range. Of course, the heat transfer gas may be ejected toward the annular concave portion E7 from any heat transfer gas ejection port other than the ejection port 206.

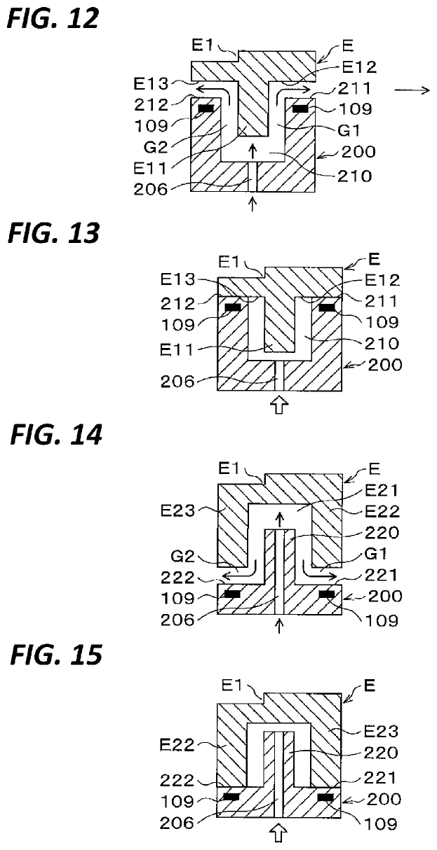

The configuration of the edge ring E and the ring mount 200 described above with reference to FIGS. 3 to 11 may be said to be one form of the edge ring E and the ring mount 200 illustrated in FIG. 12. That is, the edge ring E illustrated in FIG. 12 has an annular convex portion E11 on the lower surface side, and the ring mount 200 has an annular concave portion 210 which accommodates the convex portion E11 through a gap.

The levitation gas is ejected from the ejection port 206 toward the convex portion E11 of the edge ring E, so that the gas flows out from the gas flow path G1 defined between the outer side surface of the convex portion E11 and the inner side surface of the concave portion 210 of the ring mount 200 and between a peripheral portion E12 of the convex portion E11 and an edge portion upper end surface 211 of the concave portion 210 and the gas flow path G2 defined between the inner side surface of the convex portion E11 and the inner side surface of the concave portion 210 of the ring mount 200 and between a peripheral portion E13 of the convex portion E11 and an edge portion upper end surface 212 of the concave portion 210 of the ring mount 200. That is, the gas from the ejection port 206 flows out to the outer peripheral side and the inner peripheral side of the edge ring E. Thus, the convex portion E11 of the edge ring E is adjusted in position while levitating inside the concave portion 210.

Then, when the flow rate of the levitation gas ejected from the ejection port 206 is gradually reduced to complete the position adjustment and the ejection of the gas is stopped to cause the edge ring E to be seated on the ring mount 200, as illustrated in FIG. 13, the peripheral portion E12 of the convex portion E11 of the edge ring E and the upper end surface 211 of the concave portion 210 of the ring mount 200 come into close contact with each other, and the peripheral portion E13 of the convex portion E11 of the edge ring E and the edge portion upper end surface 212 of the concave portion 210 of the ring mount 200 come into close contact with each other. Then, a voltage is applied to the electrode 109 to firmly hold the edge ring E on the ring mount 200 by an electrostatic force, and then, a heat transfer gas is ejected from, for example, the levitation gas ejection port 206, so that the temperature of the edge ring E may be maintained in an appropriate range.

The example illustrated in FIGS. 12 and 13 shows a configuration in which the annular convex portion E11 is provided on the lower surface side of the edge ring E and the ring mount 200 has the annular concave portion 210 which accommodates the convex portion E11 through a gap, but a configuration opposite to such a pattern may also be presented in the present disclosure. That is, as illustrated in FIG. 14, there may be a configuration in which the edge ring E has an annular concave portion E21 on the lower surface side and the ring mount 200 has an annular convex portion 220 which is accommodated in the concave portion E21 through a gap.

According to this form, when the levitation gas is ejected from the ejection port 206 toward the concave portion E21 of the edge ring E, the gas hits in the concave portion E21 and levitates the edge ring E. Then, the gas flows out from the gap between the concave portion E21 and the annular convex portion 220 of the ring mount 200, the gas flow path G1 defined between the lower end surface of an outer annular wall E22 forming the concave portion E21 and the upper surface of a peripheral portion 221 of the convex portion 220, the gap between the concave portion E21 and the convex portion 220, and the gas flow path G2 defined between the lower end surface of an inner annular wall E23 and the upper surface of a peripheral portion 222 of the convex portion 220 of the ring mount 200. That is, the gas from the ejection port 206 flows out to the outer peripheral side and the inner peripheral side of the edge ring E. Thus, the edge ring E is adjusted in position while levitating on the ring mount 200.

Then, when the flow rate of the levitation gas ejected from the ejection port 206 is gradually reduced to complete the position adjustment and the ejection of the gas is stopped to cause the edge ring E to be seated on the ring mount 200, as illustrated in FIG. 15, the respective lower end surfaces of the outer annular wall E22 and the inner annular wall E23 forming the concave portion E21 come into close contact with the respective upper surfaces of the peripheral portions 221 and 222 of the convex portion 220 of the ring mount 200. Then, a voltage is applied to the electrode 109 to firmly hold the edge ring E on the ring mount 200 by an electrostatic force, and then, a heat transfer gas is ejected from, for example, the levitation gas ejection port 206, so that the temperature of the edge ring E may be maintained in an appropriate range.

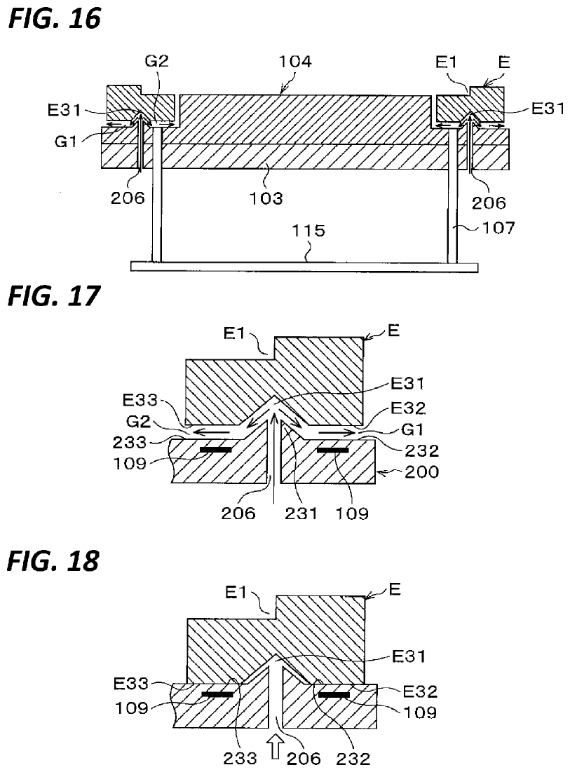

The present disclosure may also propose any forms different from such one form. In an example illustrated in FIGS. 16 to 18, the vertical cross section of an annular concave portion E31 of the edge ring E has a tapered shape that is wider toward the lower surface, while the vertical cross section of an annular convex portion 231 of the ring mount 200 has a tapered shape that is narrower toward the upper surface.

In this way, as the vertical cross section of the concave portion 31 of the edge ring E has a tapered shape that is wider toward the lower surface and the vertical cross section of the convex portion 231 of the ring mount 200 has a tapered shape that is narrower toward the upper surface, when the levitation gas is ejected from the ejection port 206 toward the concave portion E31 of the edge ring E, as illustrated in FIG. 17, the gas hits in the concave portion E31. Thus, the edge ring E levitates.

Then, the gas flows out from the gas flow path G1 defined between a peripheral lower end surface E32 of the concave portion E31 of the edge ring E and the upper surface of a peripheral portion 232 of the convex portion 231 of the ring mount 200 and the gas flow path G2 defined between a peripheral lower end surface E33 and the upper surface of a peripheral portion 233 of the convex portion 231. That is, the gas from the ejection port 206 flows out to the outer peripheral side and the inner peripheral side of the edge ring E. Thus, the edge ring E is adjusted in position while levitating on the ring mount 200. Further, since the outer shape of the edge ring E in the concave portion E31 and the outer shape of the convex portion 231 of the ring mount 200 are respectively tapered shapes, the levitation and position adjustment of the edge ring E by the levitation gas may be performed more smoothly than the example illustrated in FIGS. 14 and 15.

When the flow rate of the levitation gas ejected from the ejection port 206 is gradually reduced to complete the position adjustment, the ejection of the gas is stopped to cause the edge ring E to be seated on the ring mount 200. Thus, as illustrated in FIG. 18, the peripheral lower end surfaces E32 and E33 of the concave portion E31 of the edge ring E and the upper surfaces of the peripheral portions 232 and 233 of the convex portion 231 of the ring mount 200 come into close contact with each other. Then, a voltage is applied to the electrode 109 to firmly hold the edge ring E on the ring mount 200 by an electrostatic force, and then, a heat transfer gas is ejected from, for example, the levitation gas ejection port 206, so that the temperature of the edge ring E may be maintained in an appropriate range.

The upper surfaces of the peripheral portion 232 and 233 of the convex portion 231 of the ring mount 200 may be formed slightly lower than the surroundings, and a gap may be formed between the upper surfaces of the peripheral portions 232 and 233 and the peripheral lower end surfaces E32 and E33 of the concave portion E31 of the edge ring E, so that a heat transfer gas is supplied to the gap.

According to the present disclosure, it is possible to mount an edge ring on an edge ring mount with high accuracy.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A substrate support stage comprising:
a substrate mounting surface on which a substrate is mounted; and
a ring mount on which an edge ring is mounted so as to surround the substrate mounted on the substrate mounting surface,
wherein the ring mount is provided with a plurality of gas ejection ports configured to eject a gas toward a lower surface of the edge ring to levitate the edge ring while the edge ring is being mounted on the ring mount, thereby causing the gas to flow out from a gap between inner and outer peripheries of the lower surface of the edge ring and the ring mount.

2. The substrate support stage according to claim 1, wherein the edge ring has a concave portion on the lower surface.

3. The substrate support stage according to claim 1, wherein the plurality of gas ejection ports are equidistantly arranged in a circumferential direction of the ring mount.

4. The substrate support stage according to claim 1, wherein the ring mount is provided with an electrode configured to attract and hold the mounted edge ring by an electrostatic force.

5. The substrate support stage according to claim 1, further comprising a lift configured to raise and lower the edge ring.

6. The substrate support stage according to claim 5, wherein the lift is accommodated in each of the gas ejection ports.

7. A plasma processing system comprising:
the substrate support stage according to claim 5;
a processing container having the substrate support stage provided therein and configured to be decompressible;
a plasma processing apparatus including an elevator that raises and lowers the lift, and configured to perform a plasma processing on the substrate placed on the substrate support stage;
a transfer device including a support that supports the edge ring, and configured to insert and remove the support into and from the processing container, thereby carrying the edge ring into and out of the processing container; and
a controller configured to control the elevator and the transfer device, wherein the controller controls a supply of the gas, the elevator, and the transfer device to execute a process including:
transferring the edge ring supported by the support onto the substrate support stage;
raising the lift to deliver the edge ring from the support to the lift;
ejecting a gas from the gas ejection ports toward the lower surface of the edge ring after the raising the lift;
lowering the lift to levitate the edge ring by the ejecting of the gas; and
gradually weakening the ejecting of the gas, and then stopping the ejecting of the gas so that the edge ring is mounted on the ring mount of the edge ring.

8. A method of mounting an edge ring on a ring mount disposed around a substrate mounting surface on which a substrate is mounted, the method comprising:
mounting the edge ring on an upper surface of a lift raised from the ring mount;
lowering the lift and ejecting a gas toward a lower surface of the edge ring;
levitating the edge ring on the ring mount by the gas as the upper surface of the lift is separated from the edge ring, and causing the gas to flow out from inner and outer peripheries of the lower surface of the edge ring;
causing the gas to flow out from a gap between inner and outer peripheral surfaces of the lower surface of the edge ring and the ring mount thereby adjusting a position of the edge ring; and
stopping the ejecting of the gas and mounting the edge ring on the ring mount.

9. The method according to claim 8, further comprising: after the mounting the edge ring on the ring mount,
ejecting the gas toward the lower surface of the edge ring again to levitate the edge ring on the ring mount; and
then reducing a flow rate of the ejected gas, and subsequently stopping the ejecting of the gas so that the edge ring is mounted on the ring mount.

10. The method according to claim 8, further comprising: after the mounting the edge ring on the ring mount, attracting and holding the edge ring on the ring mount by an electrostatic force.

11. The method according to claim 8, wherein the gas ejected toward the lower surface of the edge ring is a heat transfer gas.

12. The method according to claim 8, wherein the edge ring has an annular convex portion on a side of the lower surface along a circumferential direction of the edge ring over an entire circumference,
the ring mount has an annular concave portion that accommodates the convex portion through a gap, and
a peripheral portion of the convex portion in the edge ring and an edge portion upper end surface of the concave portion come into close contact with each other when the edge ring is mounted on the ring mount.

13. The method according to claim 8, wherein the edge ring has an annular concave portion on the side of the lower surface,
the ring mount has an annular convex portion that is accommodated in the concave portion through a gap, and
a peripheral lower end surface of the concave portion in the edge ring and a peripheral portion of the convex portion in the ring mount come into close contact with each other when the edge ring is mounted on the ring mount.

14. The method according to claim 12, wherein the ring mount has an annular outer slope portion and an annular inner slope portion that are wider upward in a tapered shape, and an annular mount formed at a bottom between the outer slope portion and the inner slope portion,
the lower surface of the edge ring is provided with an annular outer taper and an annular inner taper that create a gap with the outer slope portion and the inner slope portion therebetween, respectively, when being accommodated in the ring mount,
an annular bottom is provided between the outer taper and the inner taper, each of which protrudes toward the lower surface via an annular step, and
the annular bottom comes into close contact with the annular mount of the ring mount when the edge ring is mounted on the ring mount.

15. The method according to claim 12, wherein the ring mount has an annular outer slope and an annular inner slope that are wider upward in a tapered shape, and an annular mount formed at a bottom between the outer slope and the annular inner slope,
the lower surface of the edge ring is provided with an annular outer taper and an annular inner taper that create a gap with the outer slope or the inner slope therebetween, respectively, when being accommodated in the ring mount,
an annular concave is formed between the outer taper and the inner taper, and a peripheral edge of the annular concave comes into close contact with the annular mount of the ring mount when the edge ring is mounted on the ring mount.

16. The method according to claim 13, wherein the concave of the edge ring has a tapered vertical cross section that is wider toward a lower surface, and
the convex of the ring mount has a tapered vertical cross section that is narrower toward an upper surface.
